(19) United States
(12) Patent Application Publication
(10) Pub. No.: US 2012/0141665 A1
(43) Pub. Date: Jun. 7, 2012

(54) METHOD OF AND APPARATUS FOR FORMING A METAL PATTERN

(75) Inventors: Tae-Youb KIM, Seoul (KR); Kang-Jun Baeg, Gwangju (KR); In-Kyu You, Daejeon (KR); Minseok Kim, Chungcheongbuk-do (KR); Jae Bon Koo, Daejeon (KR)

(73) Assignee: ELECTRONICS AND TELECOMMUNICATIONS RESEARCH INSTITUTE, Daejeon (KR)

(21) Appl. No.: 13/309,807

(22) Filed: Dec. 2, 2011

(30) Foreign Application Priority Data
Dec. 3, 2010 (KR) 10-2010-0122869

(51) Int. Cl. H05K 3/02; B05C 5/00

(52) U.S. Cl. 427/97.5; 427/97.4; 118/206

(57) ABSTRACT

Provided are methods of and apparatuses for forming a metal pattern. In the method, an initiator and a metal pattern are sequentially combined on a previously-formed bonding agent pattern improving adhesion and/or junction properties between the substrate and the metal. The bonding agent pattern may be formed using a reverse offset printing method. The metal pattern may be formed using an electroless electrochemical plating method. The metal pattern can be formed with improved uniformity in thickness and planar area.

### CROSS-REFERENCE TO RELATED APPLICATIONS

This U.S. non-provisional patent application claims priority under 35 U.S.C. §119 to Korean Patent Application No. 10-2010-0122869, filed on Dec. 3, 2010, in the Korean Intellectual Property Office, the entire contents of which are hereby incorporated by reference.

### BACKGROUND OF THE INVENTION

Embodiments of the inventive concepts relate to methods of and apparatuses for forming a metal pattern using a printing technique.

Traditionally, printing means a process for reproducing text, drawing and image with ink on paper. As high resolution and high accuracy printing technologies develop, there are a variety of attempts to apply the recently developed printing technologies to an electronic device fabrication. The printing is a green or environmental technology in that efficiency in using materials and process throughput can be improved using an additive process and the printing process can be performed at atmospheric pressure allowing energy saving. In addition, the printing has an advantage applicable to a large-area object using, for instance, a roll-to-roll method.

### SUMMARY

Embodiments of the inventive concepts provide metal-pattern-forming methods capable of improving electrical reliability and increasing a throughput.

Other embodiments of the inventive concepts provide metal-pattern-forming apparatuses capable of improving electrical reliability and increasing a throughput.

According to example embodiments of the inventive concepts, a method of forming a metal pattern may include forming bonding agent patterns on a substrate, providing an initiator solution on the substrate to form an initiator combined with the bonding agent pattern, providing a metal precursor solution on the substrate and performing a plating process to form a metal pattern combined with the initiator, and performing a cleaning process to remove the initiator solution and the metal precursor solution between the bonding agent patterns.

In some embodiments, the forming of the bonding agent patterns may be performed using at least one of reverse offset printing, nano-imprinting, gravure offset printing, micro-contact printing, and inkjet printing methods.

According to other example embodiments of the inventive concepts, an apparatus for forming a metal pattern may include a bonding agent solution supplying nozzle, a blanket roll configured to be three-dimensionally and pivotably movable, the bonding agent solution supplying nozzle being configured to supply a bonding agent solution onto an outer circumferential edge of the blanket roll, a conveyor belt, a substrate disposed on the conveyor belt and configured to be movable along the conveyor belt, an initiator solution supplying nozzle disposed over the conveyor belt, a metal precursor solution supplying nozzle disposed over the conveyor belt, and a cleaning solution supplying nozzle disposed over the conveyor belt.

In some embodiments, the apparatus may further include a printing substrate with projecting portions and recessed portions. The blanket roll may be configured to be able to press the printing substrate. In other embodiments, the blanket roll may include a blanket serving as the outer circumferential edge thereof and defining projecting portions and recessed portions.

### BRIEF DESCRIPTION OF THE DRAWINGS

Example embodiments will be more clearly understood from the following brief description taken in conjunction with the accompanying drawings. FIGS. 1 through 10 represent non-limiting, example embodiments as described herein.

FIG. 1 is a flow chart illustrating a method of forming a metal pattern according to example embodiments of the inventive concepts;

FIG. 2 is a flow chart illustrating a method of forming a metal pattern according to some embodiments of the inventive concepts;

FIG. 3 is a process sectional view exemplarily illustrating the first step of FIG. 2;

FIGS. 4 through 6 are process sectional views exemplarily illustrating the second to fourth steps of FIG. 2, respectively;

FIG. 7 is a sectional view exemplarily illustrating an apparatus for forming a metal pattern according to some embodiments of the inventive concepts;

FIG. 8 is a flow chart illustrating a method of forming a metal pattern according to other embodiments of the inventive concepts;

FIG. 9 is a process sectional view exemplarily illustrating the first step of FIG. 8; and

FIG. 10 is a sectional view exemplarily illustrating an apparatus for forming a metal pattern according to other embodiments of the inventive concepts.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

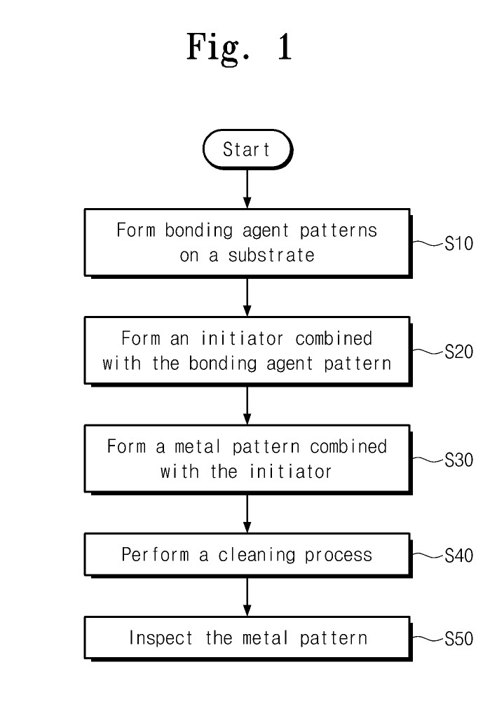

FIG. 1 is a flow chart illustrating a method of forming a metal pattern according to example embodiments of the inventive concepts.

Referring to FIG. 1, a method of forming a metal pattern according to example embodiments of the inventive concepts may include forming bonding agent patterns on a substrate (in S10), providing an initiator solution on the substrate to form an initiator combined with the bonding agent pattern (in S20), providing a metal precursor solution on the substrate and performing a plating process to form a metal pattern combined with the initiator (in S30), and performing a cleaning process to remove the initiator solution and the metal precursor solution between the bonding agent patterns (in S40). In addition, the method may further include inspecting the metal pattern after the cleaning process (in S50).

The formation of the bonding agent pattern, in S10, may be performed using at least one of reverse offset printing, nano-imprinting, gravure offset printing, micro-contact printing, and inkjet printing methods. But, example embodiments of the inventive concepts may not be limited thereto, and the bonding agent pattern may be formed using one of various methods. Hereinafter, the formation of the bonding agent pattern on the substrate will be described in more detail with reference to the accompanying drawings.

### Embodiment 1

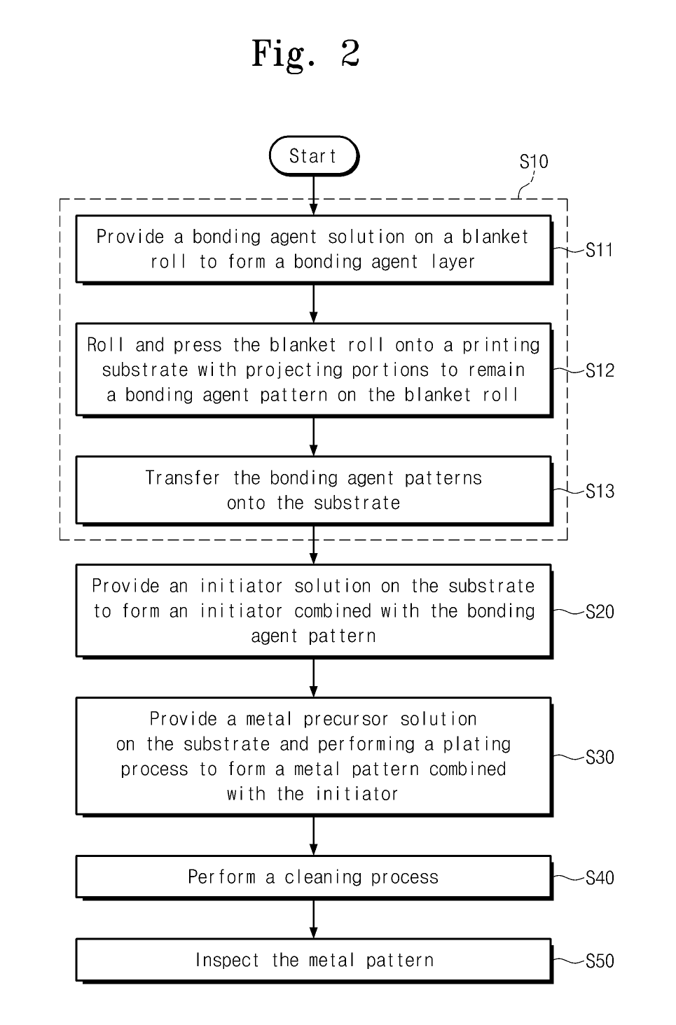

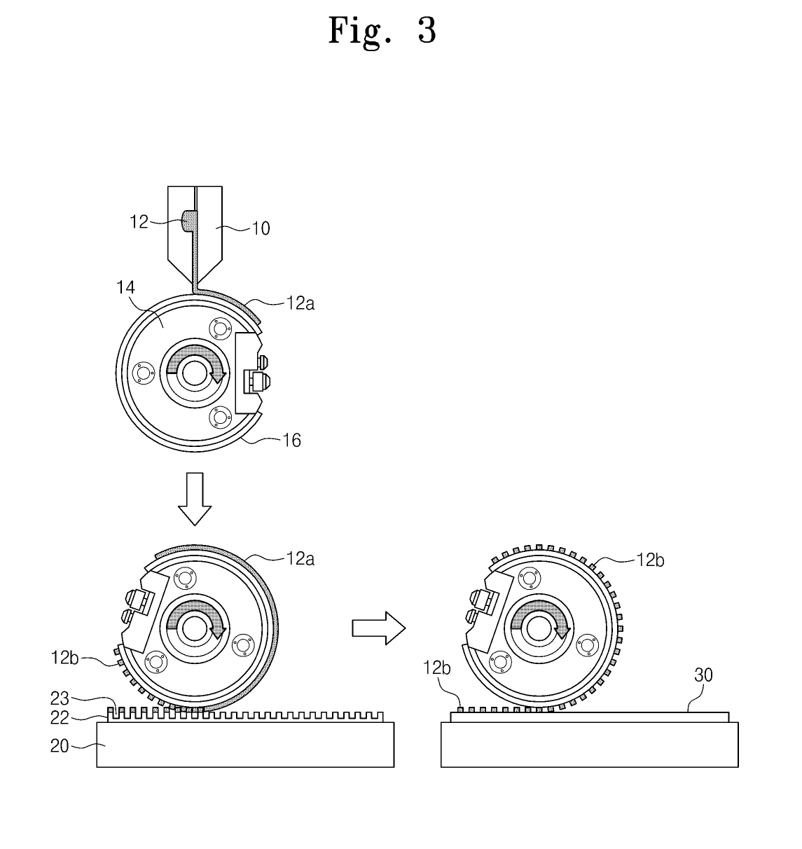

FIG. 2 is a flow chart illustrating a method of forming a metal pattern according to some embodiments of the inventive concepts. FIG. 3 is a process sectional view exemplarily illustrating the first step of FIG. 2.

Referring to FIGS. 2 and 3, bonding agent patterns 12b may be formed on a substrate 30 (in S10). The formation of the bonding agent patterns 12b may include uniformly providing a bonding agent solution 12 on a blanket roll 14 to form a bonding agent layer 12a (in S11). On an outer circumferential edge of the blanket roll 14, there is a blanket 16 of silicone. The bonding agent solution 12 may be supplied via a nozzle 10. In some embodiments, the bonding agent solution 12 may be supplied on an outer surface of the blanket roll 14 in a rotating state via the nozzle 10, thereby forming the bonding agent layer 12a with a uniform thickness.

The bonding agent solution 12 may include at least one selected from a group of 2-trimethoxysilyl ethyl-2-pyridine, aminoethylaminomethyl-phenethyltrimethoxysilane, N-2-aminoethyl-3-amino propyltrimethoxysilane, phenethyltrichlorosilane, 4-chloromethylphenylsiloxane, and 3-aminopropyltriethoxysilane (APTS).

The formation of the bonding agent pattern 12b may further include rolling and pressing the blanket roll 14 onto a printing substrate 20 provided with projecting portions 22 to remain the bonding agent patterns 12b on the blanket roll 14 (in S12). The remainder 12c of the bonding agent layer 12a may remain on the projecting portions 22, as shown in FIG. 3. The bonding agent patterns 12b may be formed to have a negative configuration of the projecting portions 22. In other words, positions of the bonding agent patterns 12b may correspond to those of recessed portions 23 interposed between the projecting portions 22. In some embodiments, the printing substrate 20 may be provided in a roll shape instead of the depicted flat shape; for instance, the printing substrate 20 may be a cliche.

The formation of the bonding agent pattern 12b may further include rolling the blanket roll 14 with the bonding agent patterns 12b on a target substrate 30 to transfer the bonding agent patterns 12b onto the substrate 30 (in S13). Then, the bonding agent patterns 12b may be combined with a surface of the substrate 30 by a chemical reaction therebetween. The substrate 30 may be, for example, a silicon substrate, a plastic substrate, a flexible film or a glass. In the case that the bonding agent solution 12 contains 3-aminopropyltriethoxysilane (APTS), a chemical reaction on the substrate 30 may be represented by the following reaction formula.

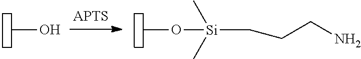

In some embodiments, an additional step of volatilizing a solvent in the bonding agent pattern 12b may be performed after the transcription of the bonding agent pattern 12b onto the substrate 30.

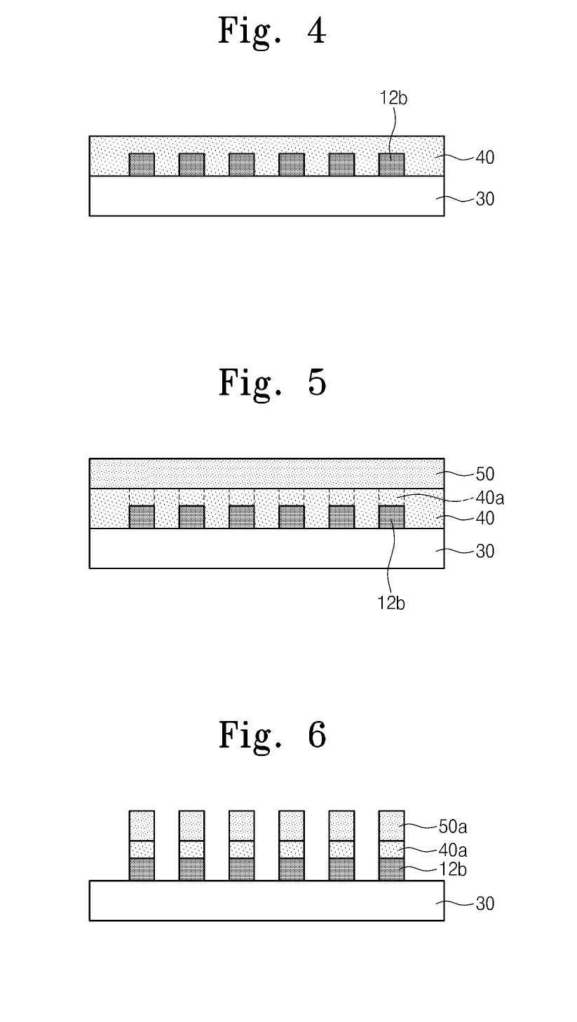

FIGS. 4 through 6 are process sectional views exemplarily illustrating the steps, shown in S20, S30, and S40, respectively, of FIG. 2.

Referring to FIGS. 2 and 4, an initiator solution 40 may be coated on the substrate 30 to form initiators 40a combined with the bonding agent patterns 12b (in S20). An adhesion or combination strength between the substrate 30 and the bonding agent pattern 12b may prevent the bonding agent patterns 12b from being detached during providing the initiator solution 40. The initiator solution 40 may contain at least one selected from a group of lithium aluminum hydride (LiAlH₄), nascent hydrogen, sodium amalgam, sodium borohydride (NaBH₄), compounds containing Sn²⁺ ions, tin(II) chloride, sulfite compounds, hydrazine (Wolff-Kishner reduction), zinc-mercury amalgam (Zn(Hg)) (Clemmensen reduction), diisobutylaluminum hydride (DIBAH), Lindlar catalyst, oxalic acid (C₂H₂O₄), formic acid (HCOOH), ascorbic acid (C₆H₈O₆), phosphites, hypophosphites, phosphorous acid, compounds containing the Fe²⁺ ion, such as iron(II) sulfate. The initiator solution 40 may be coated by using at least one of spin coating, spraying and dipping methods.

In other embodiments, the initiator solution may include nano particles, which may be formed of at least one selected from a group of boron (B), phosphorus (P), vanadium (V), chromium (Cr), manganese (Mn), iron (Fe), cobalt Co, nickel (Ni), copper (Cu), zinc (Zn), gallium (Ga), germanium (Ge), arsenic (As), selenium (Se), molybdenum (Mo),technetium (Tc), rhodium (Rh), silver (Ag), cadmium (Cd), indium (In), tin (Sn), antimony (Sb), tellurium (Te), tungsten (W), rhenium (Re), platinum (Pt), gold (Au), thallium (Tl), lead (Pb), or bismuth (Bi). The initiator solution may be a suspension of the nano particles in dispersion media. In some embodiments, the dispersion media may be water or alcohol.

In some embodiments, the bonding agent solution 12 contains 3-aminopropyltriethoxysilane (APTS), and the initiator solution is a suspension of lead (Pd) nano particles, a chemical reaction on the substrate 30 may be represented by the following reaction formula.

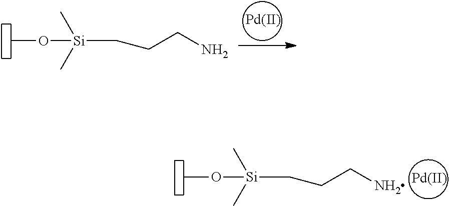

In some embodiments, an additional step of volatilizing a solvent in the initiator solution 40 may be performed, after waiting until the initiator is completely or sufficiently combined with the bonding agent pattern 12b.

Thereafter, referring to FIGS. 2 and 5, a metal precursor solution 50 may be formed on the substrate 30 and then a plating process may be performed on the resultant structure. As a result, metals 50a combined with the initiators 40a may be formed (in S30). In some embodiments, the metal precursor solution 50 may be one of an aqueous diamminesilver(I) complex, ([Ag NH₃₂]+) or a copper electroless plating solution. The copper electroless plating solution may include at least one of sodium hydroxide (NaOH), copper sulfate (CuSO₄5H₂O), potassium sodium tartrate (KNaC₄H₄O₆4H₂O), or formaldehyde (HCHO). The plating process may be performed in an electroless plating or electroplating manner. The metal precursor solution 50 may be formed using one method of dipping the substrate 30 in the metal precursor solution 50, coating the metal precursor solution 50 on the substrate 30, or spraying the metal precursor solution 50 on the substrate 30.

In the case that the bonding agent solution 12 contains 3-aminopropyltriethoxysilane (APTS) and the initiator solution and the metal precursor solution are a suspension of lead (Pd) nano particles and aqueous diamminesilver(I) complex, respectively, a chemical reaction on the substrate 30 may be represented by the following reaction formula.

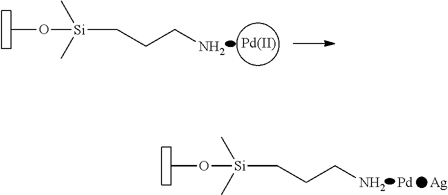

Thereafter, referring to FIGS. 2 and 6, a cleaning process may be performed to remove the initiator solution 40 and the metal precursor solution 50 between the bonding agent patterns 12b (in S40). The cleaning process may be performed using a deionized water. After the cleaning process, the metal patterns 50a may be inspected (in S50).

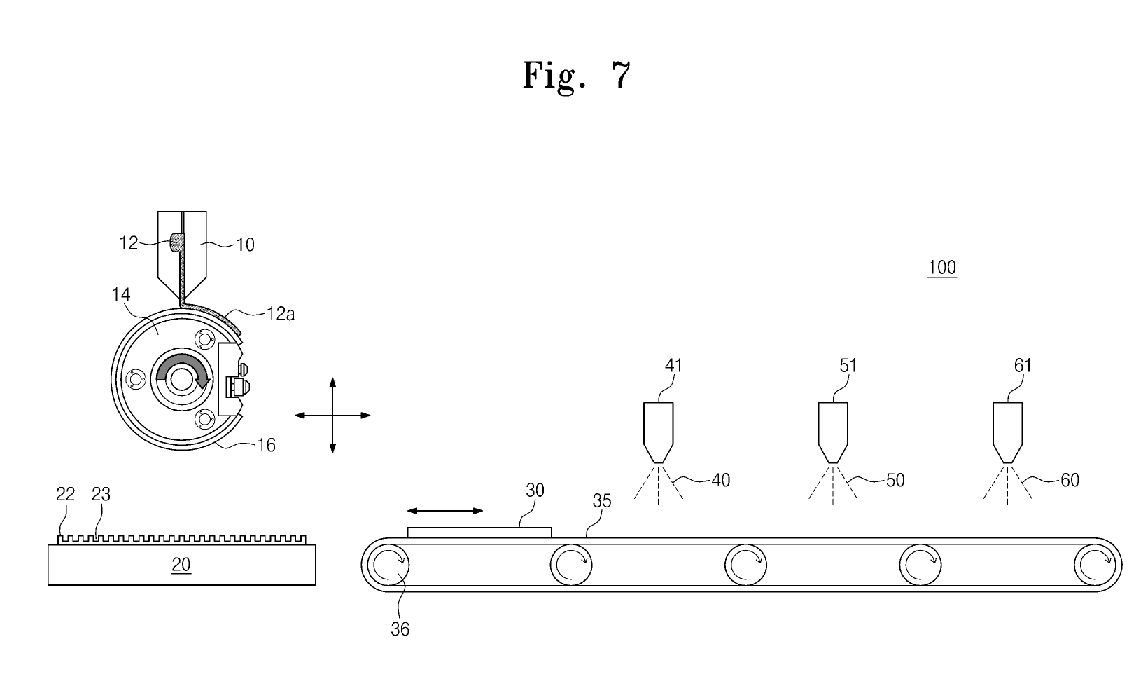

The methods of forming a metal pattern according to some embodiments of the inventive concepts may be automatically performed using an apparatus shown in FIG. 7. FIG. 7 is a sectional view exemplarily illustrating an apparatus for forming a metal pattern according to some embodiments of the inventive concepts.

Referring to FIGS. 2 and 7, a metal pattern forming apparatus 100 may include a bonding agent solution supplying nozzle 10, a blanket roll 14, a printing substrate 20, a conveyor belt 35, a conveyor belt rotating roller 36, a substrate 30, an initiator solution supplying nozzle 41, a metal precursor solution supplying nozzle 51, and a cleaning solution supplying nozzle 61. The substrate 30 may be disposed on the conveyor belt 35 and thus be movable along with the conveyor belt 35. Due to the supporting member (not shown), the blanket roll 14 may be configured to be three-dimensionally and pivotably movable relative to the printing substrate 20. A bonding agent solution 12 is supplied from the bonding agent solution supplying nozzle 10 onto an outer surface (or a blanket 16) of the blanket roll 14. During supplying the bonding agent solution 12, the blanket roll 14 may be rotated about the axis thereof. As a result, a bonding agent layer 12a may be formed on an outer circumferential edge of the blanket roll 14. After the formation of the bonding agent layer 12a, the blanket roll 14 may be moved downward to be in contact with the printing substrate 20 and then press and roll on the printing substrate 20 with projecting portions 22 and recessed portions 23 to form bonding agent patterns on the outer surface of the blanket roll 14. The blanket roll 14 including the bonding agent pattern may be transferred on the substrate 30 on the conveyor belt 35 and then transfer the bonding agent patterns thereof onto the substrate 30. Thereafter, the substrate 30 may be transferred under the initiator solution supplying nozzle 41 by the conveyor belt 35. The initiator solution supplying nozzle 41 may spray an initiator solution 40 to coat the substrate 30 with an initiator solution 40 (in S20). The substrate 30 may be transferred under the metal precursor solution supplying nozzle 51 by the conveyor belt 35. The metal precursor solution supplying nozzle 51 may spray a metal precursor solution 50 to coat the substrate 30 with a metal precursor solution 50 (in S30). The substrate 30 may be transferred under the cleaning solution supplying nozzle 61 by the conveyor belt 35. The cleaning solution supplying nozzle 61 may spray a cleaning solution 60 to perform a cleaning process on the substrate 30 (in S40).

In other embodiments, the metal pattern forming apparatus may include at least one rotating means for rotating the substrate 30. In these embodiments, the initiator solution 40, the metal precursor solution 50, and the cleaning solution 60 may be formed on the substrate 30 using a spin-coating method. In still other embodiments, the metal pattern forming apparatus may include containers for containing the initiator solution 40, the metal precursor solution 50, and the cleaning solution 60. In these embodiments, the initiator solution 40, the metal precursor solution 50, and the cleaning solution 60 may be formed on the substrate 30 using a dipping method.

### Embodiment 2

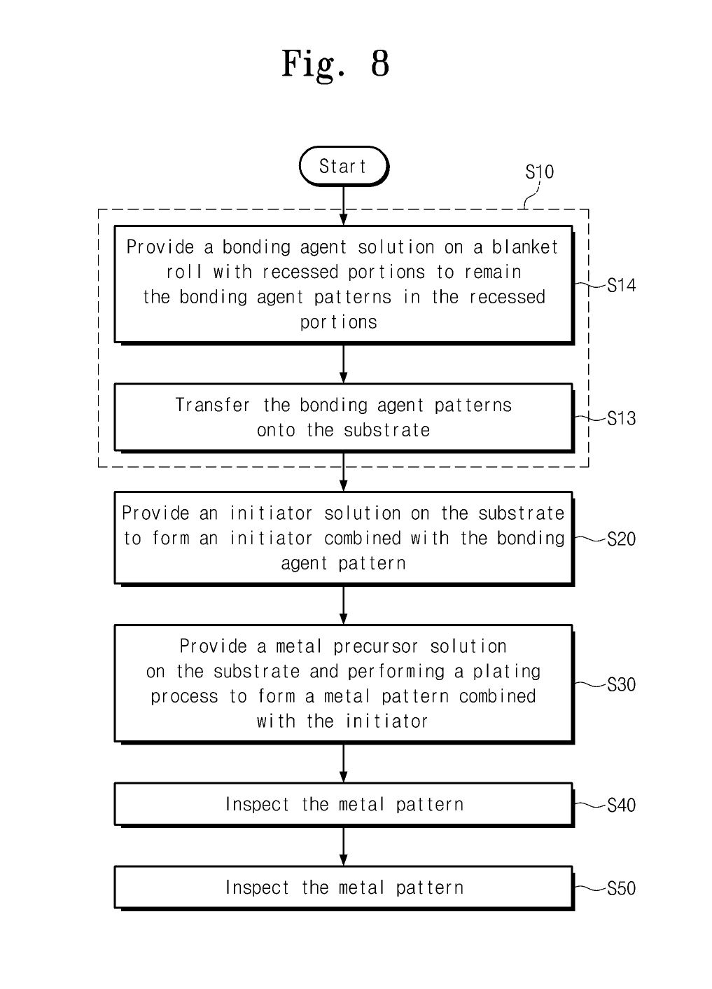

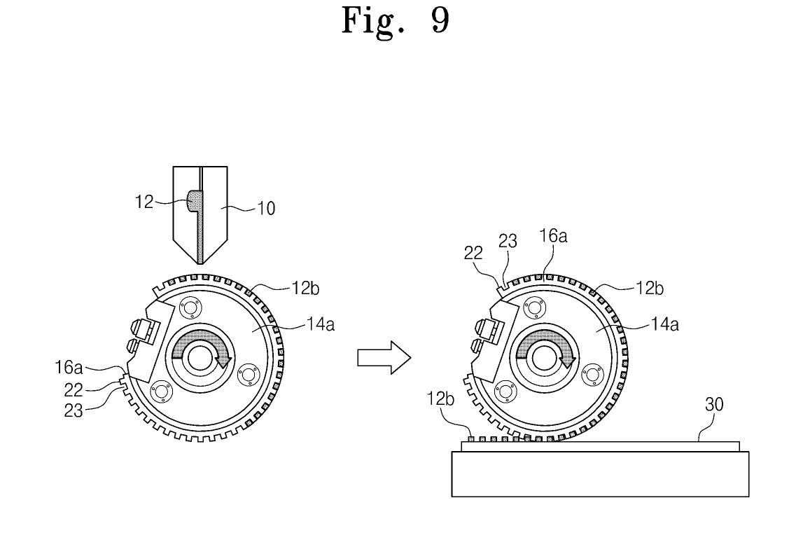

FIG. 8 is a flow chart illustrating a method of forming a metal pattern according to other embodiments of the inventive concepts. FIG. 9 is a process sectional view exemplarily illustrating the first step of FIG. 8.

Referring to FIGS. 8 and 9, the formation of the bonding agent pattern, in S10, may include forming a bonding agent solution 12 on a blanket roll 14a with recessed portions 23 in such a way that bonding agent patterns 12b remain in the recessed portions 23 (in S14) and transferring the bonding agent patterns 12b onto the substrate 30 (in S13). According to the present embodiments, the blanket roll 14a may include a blanket 16a of silicone and an outer circumferential edge of the blanket 16a may be formed to have projecting portions 22 and the recessed portions 23. The bonding agent solution 12 may be supplied onto the blanket 16a of the rotating blanket roll 14a via a bonding agent solution supplying nozzle 10, and then the bonding agent solution 12 may remain in the recessed portions 23 to form the bonding agent patterns 12b. Thereafter, the blanket roll 14a may roll on the substrate 30 to transfer the bonding agent patterns 12b onto the substrate 30. The remaining steps and conditions, except for these differences, may be performed in the substantially same or similar manner as those of the embodiments described with reference to FIGS. 2 through 7.

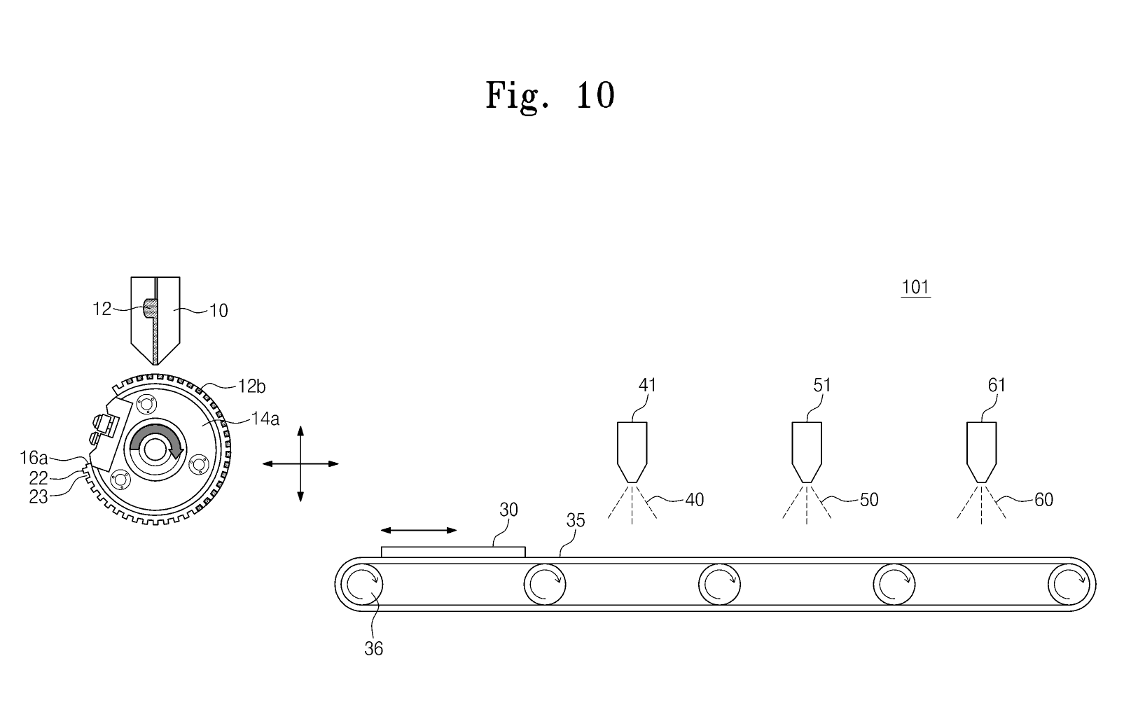

FIG. 10 is a sectional view exemplarily illustrating an apparatus for forming a metal pattern according to other embodiments of the inventive concepts.

According to the present embodiments, a metal pattern forming apparatus 101 may include the blanket roll 14a with a blanket 16a of silicone, and an outer circumferential edge of the blanket 16a may be formed to have projecting portions 22 and the recessed portions 23. In some embodiments, the apparatus 101 may be configured not to include the printing substrate 20 of FIG. 7, unlike the previous embodiments, while the remaining elements may be configured in the substantially same or similar manner as those of the embodiments described with reference to FIG. 7.

In some embodiments, the afore-mentioned metal-pattern-forming methods may be applied to form electrodes and interconnection lines for a display backplane. In other embodiments, the afore-mentioned metal-pattern-forming methods may be applied to form a RFID or a sensor. But example embodiments of the inventive concepts may not be limited thereto.

According to example embodiments of the inventive concepts, the initiator and the metal pattern are sequentially combined on the previously-formed bonding agent pattern, and this enables to improve adhesion and/or junction properties between the substrate and the metal. Accordingly, the metal pattern can be minutely formed without undesirable pattern loss and metal interconnection lines and electrodes can be formed with improved electronic and/or electric reliability, as compared with the case that the initiator and the metal pattern are directly formed on the substrate without the bonding agent pattern. In some embodiments, the bonding agent pattern may be formed using a printing technique for a consecutive process, such as a reverse offset printing method, which leads to increasing a throughput. In some embodiments, the metal pattern may be formed using an electroless electrochemical plating method, and thus, it is possible to reduce the metal layer from being oxidized and to improve an electric property of the metal interconnection line. Furthermore, even at the final step, the metal pattern can be formed with improved uniformity in thickness and planar area.

1. A method of forming a metal pattern, comprising:
forming bonding agent patterns on a substrate;
providing an initiator solution on the substrate to form an initiator combined with the bonding agent pattern;
providing a metal precursor solution on the substrate and performing a plating process to form a metal pattern combined with the initiator; and
performing a cleaning process to remove the initiator solution and the metal precursor solution between the bonding agent patterns.

2. The method of claim 1, wherein the forming of the bonding agent patterns is performed using at least one of reverse offset printing, nano-imprinting, gravure offset printing, micro-contact printing, and inkjet printing methods.

3. The method of claim 1, wherein the forming of the bonding agent patterns comprises:
providing a bonding agent solution on a blanket roll to form a bonding agent layer;
rolling and pressing the blanket roll onto a printing substrate provided with projecting portions to remain the bonding agent patterns on the blanket roll, the projecting portions having a first type configuration and the bonding agent patterns having a second type configuration corresponding to a negative of the first type configuration; and
transferring the bonding agent patterns onto the substrate.

4. The method of claim 3, wherein the forming of the bonding agent patterns further comprises volatilizing a solvent in the bonding agent solution.

5. The method of claim 3, wherein the bonding agent solution contains at least one selected from a group of 2-trimethoxysilyl ethyl-2-pyridine, aminoethylaminomethyl-phenethyltrimethoxysilane, N-2-aminoethyl-3-amino propyltrimethoxysilane, phenethyltrichlorosilane, 4-chloromethylphenylsiloxane, and 3-aminopropyltriethoxysilane (APTS).

6. The method of claim 1, wherein the forming of the bonding agent patterns comprises:
providing a bonding agent solution on a blanket roll with recessed portions to remain the bonding agent patterns in the recessed portions; and
transferring the bonding agent patterns onto the substrate.

7. The method of claim 1, wherein the initiator solution contains at least one selected from a group of lithium aluminum hydride (LiAlH₄), nascent hydrogen, sodium amalgam, sodium borohydride (NaBH₄), compounds containing Sn²⁺ ions, tin(II) chloride, sulfite compounds, hydrazine, zinc-mercury amalgam, diisobutylaluminum hydride, Lindlar catalyst, oxalic acid (C₂H₂O₄), formic acid (HCOOH), ascorbic acid (C₆H₈O₆), phosphites, hypophosphites, phosphorous acid, compounds containing Fe²⁺ ions, or iron(II) sulfate.

8. The method of claim 1, wherein the initiator solution contains nano particles, the nano particle is at least one selected from a group of boron (B), phosphorus (P), vanadium (V), chromium (Cr), manganese (Mn), iron (Fe), cobalt Co, nickel (Ni), copper (Cu), zinc (Zn), gallium (Ga), germanium (Ge), arsenic (As), selenium (Se), molybdenum (Mo),technetium (Tc), rhodium (Rh), silver (Ag), cadmium (Cd), indium (In), tin (Sn), antimony (Sb), tellurium (Te), tungsten (W), rhenium (Re), platinum (Pt), gold (Au), thallium (Tl), lead (Pb), or bismuth (Bi).

9. The method of claim 1, wherein the metal precursor solution contains one of an aqueous diamminesilver(I) complex, ([Ag NH₃₂]+) or a copper electroless plating solution.

10. The method of claim 9, wherein the copper electroless plating solution contains at least one of sodium hydroxide (NaOH), copper sulfate (CuSO₄5H₂O), potassium sodium tartrate (KNaC₄H₄O₆4H₂O), or formaldehyde (HCHO).

11. The method of claim 1, wherein the providing of the metal precursor solution is performed using one method of dipping the substrate in the metal precursor solution, coating the metal precursor solution on the substrate, or spraying the metal precursor solution on the substrate.

12. The method of claim 1, wherein the cleaning process is performed using a deionized water.

13. An apparatus for forming a metal pattern, comprising:
a bonding agent solution supplying nozzle;
a blanket roll configured to be three-dimensionally and pivotably movable, the bonding agent solution supplying nozzle being configured to supply a bonding agent solution onto an outer circumferential edge of the blanket roll;
a conveyor belt;
a substrate disposed on the conveyor belt and configured to be movable along the conveyor belt;
an initiator solution supplying nozzle disposed over the conveyor belt;
a metal precursor solution supplying nozzle disposed over the conveyor belt; and
a cleaning solution supplying nozzle disposed over the conveyor belt.

14. The device of claim 13, further comprising a printing substrate with projecting portions and recessed portions, wherein the blanket roll is configured to be able to press the printing substrate.

15. The device of claim 13, wherein the blanket roll comprises a blanket serving as the outer circumferential edge thereof and defining projecting portions and recessed portions.
